(19) United States
(12) Patent Application Publication
(10) Pub. No.: US 2007/0109065 A1
(43) Pub. Date: May 17, 2007

(54) Methods and apparatus for the reduction of local oscillator pulling in zero intermediate frequency transmitters

(76) Inventor: Spyros Pipilos, Athens (GR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/431,174

(22) Filed: May 10, 2006

Related U.S. Application Data
(60) Provisional application No. 60/679,239, filed on May 10, 2005.

(51) Int. Cl. H03B 5/08

(52) U.S. Cl. 331/167

(57) ABSTRACT

The “pulling” of a local oscillator in zero intermediate frequency (IF) transmitters with “on” frequency voltage controlled oscillator (VCO), is well known in the art to drastically degrade system performance of wireless transmitters. While complex solutions to the problem do exist the disclosed invention provides a less complex but rigid method for the reduction of the phenomena. In accordance with the disclosed teachings and techniques magnetic coupling is reduced by placing spiral inductors in a manner canceling the effects of their respective magnetic fields. Furthermore the VCO and transmitter are placed in sufficient distance from each other to further reduce magnetic interference. It is further shown that placing the VCO and the transmitter each in the confines of grounded guard rings further reduces the interference. In yet further teachings of the invention different power supplies are used to feed the VCO and the transmitter, further reducing electromagnetic coupling.

### CROSS-REFERENCE TO RELATED APPLICATION

This application claims the benefit of U.S. Provisional Patent Application No. 60/679,239 filed May 10, 2005.

### BACKGROUND OF THE INVENTION

1. Field of the Invention

The present invention relates generally to the design of wireless transmitters, and more particularly to the design and layout of wireless transmitters targeted at reducing the phenomenon of local oscillator pulling.

2. Prior Art

The “pulling” of a local oscillator (LO) in zero intermediate frequency (IF) transmitters with “on” frequency voltage controlled oscillator (VCO), is well known in the art to drastically degrade system performance of wireless transmitters. Specifically, pulling is the modulation of a LO signal, due to unwanted coupling, from an interference, appearing at the same frequency. This phenomenon is graphically explained with reference to FIG. 1. The VCO generates a LO frequency f_{LO} 110. However there is also present an interference 120 around the same frequency of f_{LO} 110. Due to coupling effects there is a pulling of the f_{LO} 110 frequency resulting in a frequency scheme 140, undesirable for the operations of transmitters in general.

A person skilled in the art would easily identify the dominant sources for coupling mechanisms and would generally group them into three categories: a) magnetic coupling of inductive components; b) electrical coupling through a common substrate; and, c) electromagnetic coupling through power supplies (see FIG. 4 for details). The magnetic coupling between a transmitter 210 and a VCO 220 are shown with respect to FIG. 2. The magnetic coupling occurs when inductors are in a close enough proximity to have meaningful coupling between the inductive components, such as inductor 215 in the transmitter circuit and inductor 225 in the VCO circuit. Electrical coupling is shown with reference to FIG. 3 where an electrical coupling from a transmitter circuit to a VCO circuit through a substrate 310 is shown. It is well known in the art that coupling, such as demonstrated by circuits 312 and 314, are common in circuits placed on the same substrate, causing coupling effects and thereby the undesirable phenomenon of LO frequency pulling. The effects of electromagnetic coupling are shown with reference to FIG. 4 where the connection of a transmitter 410 and a VCO 420 to the power supply are shown. Specifically, transmitter 410 is connected to V_{cc} via a bonding wire represented by inductor 430, a pad 440 placed on the chip to which the bonding wire connects, and further through parasitic interconnect depicted by element 450-A. Transmitter 410 is connected to Vₛₛ via a bonding wire represented by inductor 470, a pad 460 placed on the chip to which the bonding wire connects, and further through parasitic interconnect depicted by element 450-B. Similarly, VCO 420 is connected to V_{cc} via a bonding wire represented by inductor 430, a pad 440 placed on the chip to which the bonding wire connects, and further through parasitic interconnect depicted by element 450-C. VCO 420 is connected to Vₛₛ via a bonding wire represented by inductor 470, a pad 460 placed on the chip to which the bonding wire connects, and further through parasitic interconnect depicted by element 450-D. Coupling between parasitic interconnects 450-A to 450-C and coupling between parasitic interconnects 450-B to 450-D results in this third mode of interference.

In order to avoid the phenomenon of LO pulling, different approaches have been used in prior art solutions. For example, in one prior art solution the VCO oscillates at double the LO frequency, then a frequency divider is used to produce the final LO frequency. In a more complicated prior art solution the frequency scheme uses a VCO running at ⅔ of the LO frequency followed by a mixer that mixes the ⅔ LO with a ⅓ LO thereby producing the final LO frequency. Although the above mentioned techniques overcome the LO “pulling”, they lead to a more complicated system, increasing in this way the IC area as well as the power consumption.

It would therefore be advantageous to provide for a solution to the LO frequency pulling that does not require complex circuitry. It would be further advantageous if such a solution would be based on specific design practices that can be made compatible with standard chip design practices and techniques.

### BRIEF DESCRIPTION OF THE DRAWINGS

FIG. 1 is a schematic frequency diagram showing the phenomenon of frequency pulling (prior art).

FIG. 2 is a schematic diagram describing the interference caused by coupling between a transmitter and a VCO circuit (prior art).

FIG. 3 is a schematic diagram describing the interference caused by electrical coupling through a common substrate (prior art).

FIG. 4 is a schematic diagram describing the interference caused by electromagnetic coupling through the power supply interconnect (prior art).

FIG. 5 is a circuit showing the placement of inductive elements having opposite currents.

FIG. 6 is a layout of a transmitter chip with a layout in accordance with the teachings of the disclosed invention.

FIG. 7 is a layout of a transmitter and VCO portions each having a grounded guard ring.

FIG. 8A is a schematic of RC decoupling network to at least reduce the power supply interference.

FIG. 8B is an exemplary bonding diagram for 90° power supply bonding.

FIG. 9 is a design flowchart in accordance with the teachings of the disclosed invention.

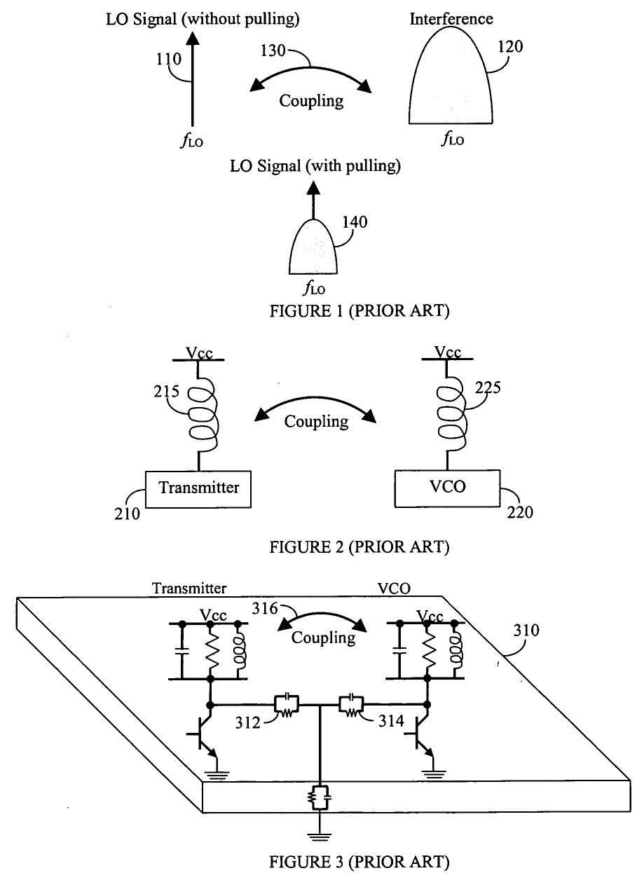

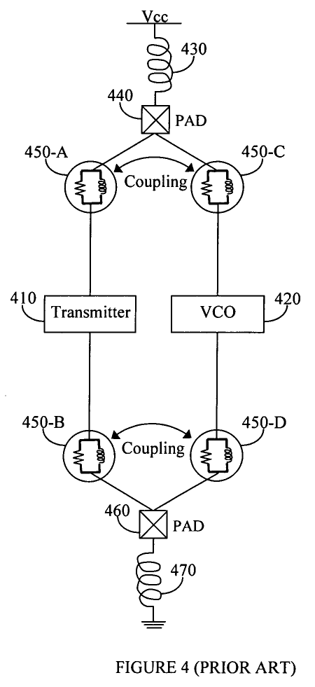

### DETAILED DESCRIPTION OF THE PREFERRED EMBODIMENTS

By contrast to the methods and techniques taught in prior-art solutions, a different approach is proposed in the teachings made by the inventor. Specifically, the approach taught for the purpose of minimizing voltage controlled oscillator (VCO) “pulling” is to minimize the effects that generate the phenomenon. Therefore specific techniques must be used and adhered to in order to ensure the minimization or elimination of the VCO pulling effect.

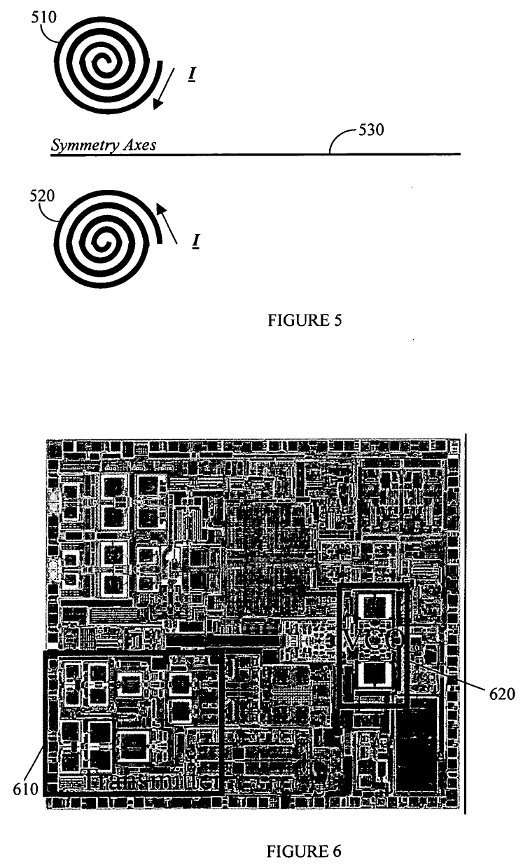

Reference is now made to FIG. 5 where an exemplary and non-limiting implementation of the placement of inductive elements is shown. In order to minimize the magnetic coupling of inductive components 510 and 520 a differential topology is used in conjunction with appropriate layout techniques. It is well known that the electromagnetic field of two spiral inductors, for example inductors 510 and 520, exited by opposite currents (opposite winding sense), is nullified on the horizontal symmetry axes 530. It would therefore be advantageous to ensure, at least through appropriate layout that such inductors are placed in a manner conducive to such nullification of the coupling effect. It is of particular importance with respect to inductors from different circuits, for example, inductors belonging to a transmitter and a VCO having a coupling due to their proximity to each other. Another important characteristic is that the electromagnetic field is degrading rapidly with the distance. Therefore, as further shown with reference to FIG. 6, it would be advantageous to place circuits such as a transmitter 610 and a VCO 620 at a maximal distance possible. As a result of such placement there is ensured the minimization of the inductive coupling between such circuits, for example, transmitter 610 and VCO 620.

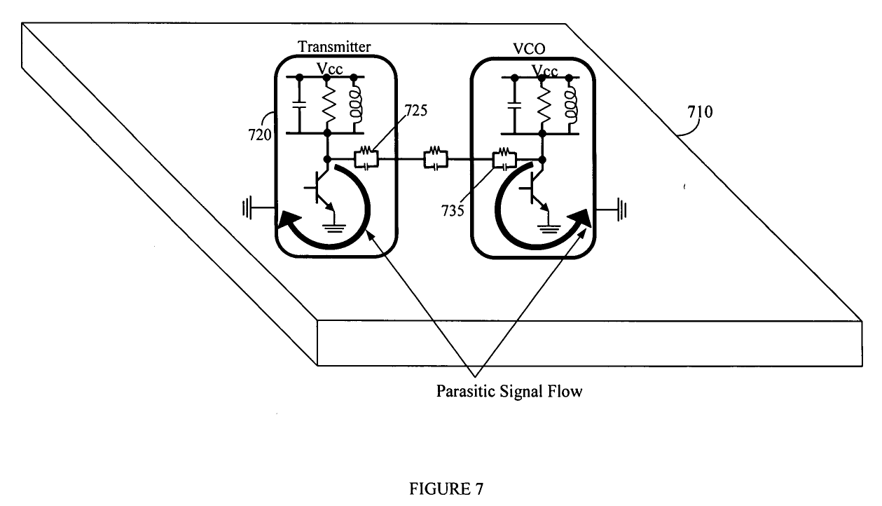

Referring now to FIG. 7, there is shown an exemplary and non-limiting implementation of circuits each having its own guard ring to minimize electrical coupling. Specifically, in order to minimize the electrical coupling through common substrate 710, grounded “guard rings” 720 and 730 are to be used around critical blocks, for example, around a transmitter and a VCO. The use of such guard rings is to act as a signal sink, as the coupling circuits 725 and 735 are each grounded. As a result an increase of the isolation between critical blocks is achieved, for example, between a transmitter and a VCO. The isolation is further increased as the distance between the blocks is increased.

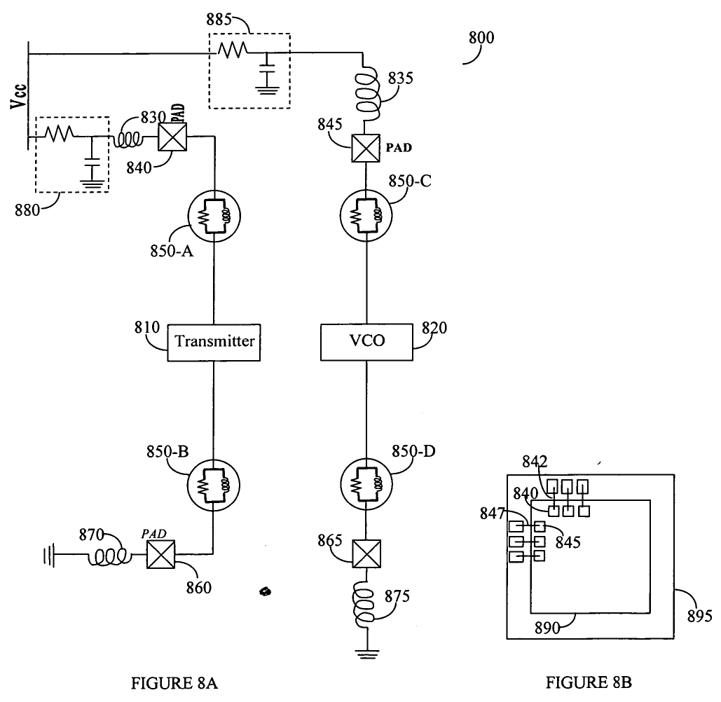

Reference is now made to FIG. 8A where an exemplary and non-limiting schematic of separate power supplies provided to critical blocks, for example a transmitter 810 and a VCO 820, with an RC network is shown. Specifically, in order to minimize the electromagnetic coupling common to the usage of a single power supply, different power supply connections are used for transmitter 810 and VCO 820. As a result the coupling due to the common parasitic interconnect depicted by circuits 850-A and 850-B of transmitter 810 supply path and parasitic interconnect circuits 850-C and 850-D of VCO 820 is significantly reduced. Moreover, external RC decoupling networks 880 and 885 to transmitter 810 path and VCO 820 path respectively, are used to further reduce the power supply coupling. RC networks 880 and 885 may be placed as part of package 895 of the chip. With reference to FIG. 8B there is shown an exemplary and non-limiting bonding of pads 840 and 845. In accordance with the disclosed invention, bonding wires 842 and 847, that connect the internal power supplies to the external power lines, i.e., connecting chip 890 pads to the pads of package 895, have a 90° placement of each other in order to minimize electromagnetic coupling between them.

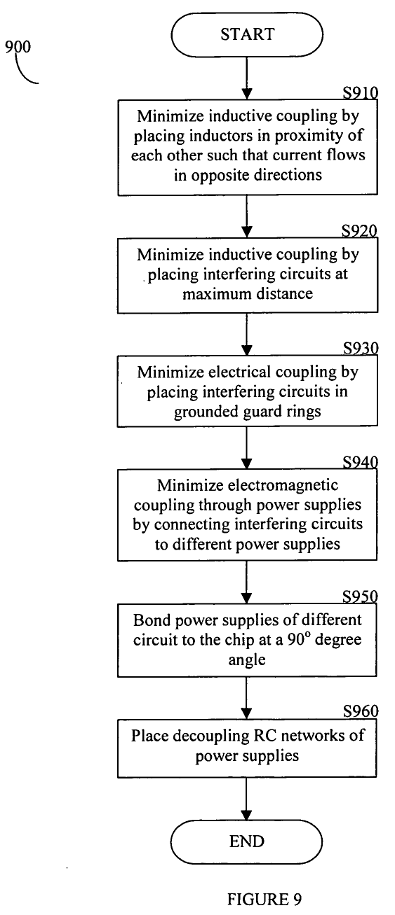

Reference is now made to FIG. 9 where an exemplary and non-limiting design flowchart 900 for a device including certain critical blocks, such as a transmitter and a VCO is shown. In step S910 the inductive coupling is minimized by placing inductors that have to reside in proximity of each other such that the current flow through the inductors is such that the interference is reduced, i.e. the current flows in the same direction for corresponding wires of the two inductors (or other conductors) that are effectively parallel to each other (opposite winding sense by reversal of the winding direction as in FIG. 5, or by providing currents of opposite directions in two windings having the same physical winding sense). A proximity threshold for determination of the effect of a coupling between proximate inductors may vary between applications, some being more sensitive to the coupling thereby establishing a lower value for inductive coupling for the purpose of placing the inductors in the manner suggested in this step S910. In step S920 inductors throughout the layout are placed at a maximum distance from each other. This step takes place as the inductive coupling is reduced as the distance grows larger. In one embodiment of the disclosed invention inductors that have been placed in accordance with step S910 are not moved with respect to each other, thereby reducing the effective number of inductors that require handling. In another embodiment of the disclosed invention only those inductors that belong to separate critical blocks are placed in a maximal distance from each other. In step S930 critical blocks that may cause interference with the operation of other blocks or that are impacted from interference of other blocks, are placed within the confines of a guard ring. The guard ring is further grounded to the system ground causing interferences from one block to be grounded in respect of another block. In step S940 the power supplies of blocks that either suffer from interference or cause interference to other blocks are connected to separate power supply pads from the power supply pads of another block. In step S950 the bonding of power supplies that are close to each other, for example, neighboring Vcc pads, are bonded in 90° degrees of each other. In step S960 decoupling resistor-capacitor (RC) networks are placed on the power supply lines to further reduce interference, the RC value being calculated to ensure that the interference frequencies are minimized. A person skilled in the art would realize that some or all of these steps may be used for a specific implementation. A person skilled in the art would further notice that the order of these steps are only exemplary and other sequences may take place.

In accordance with the disclosed invention there have been shown special layout techniques for the purpose of minimizing VCO pulling due to the modulated signal of a zero IF transmitter. Measurement results of a circuit, such as the exemplary device shown in FIG. 6, prove that the VCO pulling is drastically reduced, resulting in a system that does not present any performance degradation due to pulling effects. A person skilled-in-the-art would readily realize that a computer software product comprising a plurality of instructions designed to be executed on a computer system, and utilizing the methods disclosed herein, may be used to identify the areas where design modifications in accordance with the disclosed inventions are needed. Such a computer software product may further provide directions so as to the necessary course of action to correct an initially problematic design to overcome the frequency pulling in accordance with the principles taught herein.

Thus while certain preferred embodiments of the present invention have been disclosed and described herein for purposes of illustration and not for purposes of limitation, it will be understood by those skilled in the art that various changes in form and detail may be made therein without departing from the spirit and scope of the invention.

What is claimed is:

1. A layout method for a system on a monolithic semiconductor for minimization of frequency pulling, the method comprising one or more of:
placing at least a first circuit element and a second circuit element, said first circuit element and said second circuit element potentially having an inductive coupling, such that current flow through wires of said first circuit element and said second circuit element, the wires being essentially parallel on the symmetry axis of said first circuit element and said second circuit element, is in the same direction;
placing at least a third circuit element and a fourth circuit element potentially having an inductive coupling at a maximal distance from each other with respect to the dimensions of said monolithic semiconductor;
placing at least a fifth circuit element potentially having an electrical coupling with a sixth circuit element in a grounded guard ring; and,
connecting at least a seventh circuit element potentially having an electromagnetic coupling through the power supply with an eighth circuit element to a separate power supply pad.

2. The method of claim 1, further comprising:
bonding the bonding wire of a first power supply pad and the bonding wire of a second power supply pad, said first pad connected to a different circuit than the circuit connected to said second power supply pad, at an angle of ninety degrees

3. The method of claim 1, further comprising:
connecting an external resistor-capacitor network to at least power supply pad.

4. The method of claim 1, wherein said circuit element is at least one of: voltage controller oscillator, transmitter.

5. A monolithic semiconductor device layout in accordance with the method of claim 1.

6. A circuit having a transmitter and a voltage controlled oscillator (VCO) wherein the transmitter and the VCO comprising at least one of:
an inductive element of the transmitter and an inductive element of the VCO having an inductive coupling, the inductive elements being placed such that current flow on the symmetry axis is in opposite directions;
an inductive element of the transmitter and an inductive element of the VCO having an inductive coupling, the inductive elements being placed at a maximal distance from each other;
the transmitter having an electrical coupling with the VCO circuit being placed in a grounded guard ring;
the VCO circuit having an electrical coupling with the transmitter circuit being placed in a grounded guard ring;
the transmitter having an electromagnetic coupling through the power supply with the VCO being connected to a separate power supply pad;
the VCO having an electromagnetic coupling through the power supply with said transmitter being connected to a separate power supply pad;
a bonding wire of the transmitter power supply pad and a bonding wire of said VCO power supply pad, being connected at an angle of ninety degrees; and,
external resistor-capacitor network connected to at least a power supply pad.

7. A monolithic semiconductor device comprising the circuit of claim 6.

8. A design method of semiconductor device comprising:
identifying current directions through a first inductor and a second inductor located in proximity to each other, and laying out said first inductor and said second inductor until the direction of the flow of current along the symmetry axis of said first inductor and said second inductor are in the same direction;
calculating the maximal possible distance between at least two inductors of said semiconductor device, and laying out said at least two inductors accordingly;
identifying at least a first block and a second block of said semiconductor device having an electrical coupling, and laying out at least one of said first block and said second block inside a grounded guard ring;
identifying an electromagnetic coupling between a third block and a fourth block through the power supply of said semiconductor device, and connecting said third block to a separate power supply pad of the power supply pad of said fourth block;
identifying supply pads of said third block and said fourth block causing a coupling interference between said third block and said fourth block, and connecting the bonding wires to the power supply pads at an angle of ninety degrees; and,
connecting an external resistor-capacitor network to at least a power supply pad of said semiconductor device;
the frequency pulling due to modulated signal of a zero intermediate frequency transmitter is thereby minimized.

9. The method of claim 8, further comprising:
identifying circuit elements in a circuit that have at least one of: electrical coupling, electromagnetic coupling, interference coupling, power coupling.

10. The method of claim 9, wherein said circuit is implemented on a monolithic semiconductor device.

11. A computer software product comprising a plurality of instructions executable on a computer, that when executed perform the method of claim 8.
